(19) United States
(12) Patent Application Publication
(10) Pub. No.: US 2016/0351612 A1
(43) Pub. Date: Dec. 1, 2016

(54) IMAGE SENSOR DEVICES

(71) Applicant: Silicon Optronics, Inc., Hsinchu (TW)

(72) Inventors: Pai-Chun ZUNG, Hsinchu (TW); XIAODONG LUO, Hsinchu (TW)

(21) Appl. No.: 15/167,311

(22) Filed: May 27, 2016

(30) Foreign Application Priority Data
May 29, 2015 (TW) 104117367

(51) Int. Cl. H01L 27/146

(52) U.S. Cl. CPC H01L 27/14636; H01L 27/14643

(57) ABSTRACT

An image sensor device is provided. The image sensor device includes a substrate including a central area and a peripheral area, a sensing area located at the central area of the substrate, a plurality of I/O pads located at the peripheral area of the substrate, and a plurality of metal wires disposed above the substrate which extend from the central area to the peripheral area of the substrate and are electrically connected to the I/O pads, wherein none of the metal wires overlies the sensing area.

### CROSS REFERENCE TO RELATED APPLICATIONS

This Application claims priority of Taiwan Patent Application No. 104117367, filed on May 29, 2015, the entirety of which is incorporated by reference herein.

### TECHNICAL FIELD

The technical field relates to an image sensor device capable of effectively controlling an electric field.

### BACKGROUND

An image sensor device is a kind of semiconductor devices that transforms optical images into electrical signals. Image sensor devices can be generally classified into charge coupled devices (CCDs) image sensor devices and complementary metal oxide semiconductor (CMOS) image sensor devices. Among these image sensor devices, a CMOS image sensor device comprises a photodiode for detecting incident light and transforming it into electrical signals, and logic circuits for transmitting and processing the electrical signals.

Conventionally, in order to pull droplets above an image sensor device, disposition of the image sensor device on a printed circuit board (PCB) is required. Another high-voltage component is disposed on the printed circuit board and applies high voltage therethrough to the image sensor device to generate an electric field to drive the droplets. However, in this manner, applying a relatively high voltage value is required for driving the droplets and precisely controlling the direction and speed of the droplet movement is difficult.

Therefore, development of an image sensor device capable of effectively controlling an electric field to facilitate droplet movement is desirable.

### SUMMARY

In accordance with one embodiment of the invention, an image sensor device is provided. The image sensor device comprises a substrate comprising a central area and a peripheral area; a sensing area located at the central area of the substrate; a plurality of I/O pads located at the peripheral area of the substrate; and a plurality of metal wires disposed above the substrate which extend from the central area to the peripheral area of the substrate and are electrically connected to the I/O pads, wherein none of the metal wires overlies the sensing area.

The sensing area comprises photoelectric conversion units.

The photoelectric conversion unit comprises a photodiode (PD).

In one embodiment, one of the I/O pads is electrically connected to one of the metal wires.

In this embodiment, the present image sensor device further comprises an external circuit electrically connecting to the I/O pads and another substrate.

In this embodiment, the voltage of the metal wires is controlled by the another substrate through the external circuit.

In this embodiment, the another substrate may be made of ceramic material, silicon, glass or other suitable materials.

In one embodiment, one of the I/O pads is electrically connected to the plurality of metal wires.

In this embodiment, the present image sensor device further comprises an external circuit electrically connecting to the I/O pads and another substrate.

In this embodiment, the voltage of the metal wires is controlled by the another substrate through the external circuit.

In this embodiment, the another substrate may be made of ceramic material, silicon, glass or other suitable materials.

In one embodiment, one of the I/O pads is electrically connected to one of the metal wires.

In this embodiment, the present image sensor device further comprises an internal circuit disposed in the substrate which is electrically connected to the I/O pads.

In this embodiment, the voltage of the metal wires is controlled by the image sensor device through the internal circuit.

In one embodiment, one of the I/O pads is electrically connected to the plurality of metal wires.

In this embodiment, the present image sensor device further comprises an internal circuit disposed in the substrate which is electrically connected to the I/O pads.

In this embodiment, the voltage of the metal wires is controlled by the image sensor device through the internal circuit.

In the invention, the metal wires (a metal gate) with the specific wire density, gap width, wire width, wire thickness and pad/wire arrangement (for example, one I/O pad electrically connecting to one metal wire or one I/O pad electrically connecting to one metal wire group (comprising a plurality of metal wires)) extended from the central area to the peripheral area of the substrate are disposed above the image sensor device and provide proper potential difference and electric-field direction through an independent external circuit (for example, electrically connecting to a printed circuit board) or an independent internal circuit capable of independently controlling the turning on/off of the voltage, the timing of the turning on/off of the voltage and the voltage values of each metal wire or each group of the metal wires to successfully pull droplets above the image sensor device and make the droplets move in accordance with a desired speed and direction. In the invention, the density of the metal wires above the image sensor device is adjusted and the sensing area is exposed. In this situation, the sensing effect of the sensing area remains and the applied voltage is effectively reduced. Additionally, the internal circuit capable of controlling the metal wires is integrated into the same image sensor device, effectively reducing cost.

A detailed description is given in the following embodiments with reference to the accompanying drawings.

### BRIEF DESCRIPTION OF THE DRAWINGS

The invention can be more fully understood by reading the subsequent detailed descriptions and examples with references made to the accompanying drawings, wherein:

FIG. 1 shows a top view of an image sensor device in accordance with an embodiment of the invention;

FIG. 2 shows a top view of an image sensor device in accordance with an embodiment of the invention;

FIG. 3 shows a top view of an image sensor device in accordance with an embodiment of the invention; and

FIG. 4 shows a top view of an image sensor device in accordance with an embodiment of the invention.

### DETAILED DESCRIPTION

The following description is of the best-contemplated mode of carrying out the invention. This description is made for the purpose of illustrating the general principles of the invention and should not be taken in a limiting sense. The scope of the invention is best determined by reference to the appended claims.

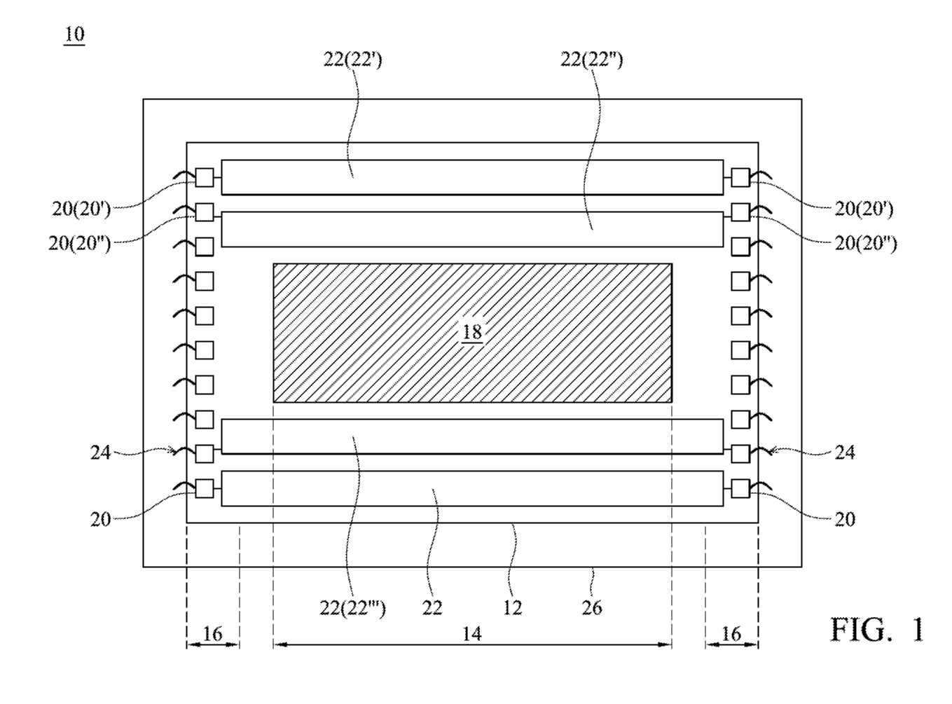

In accordance with one embodiment of the invention, an image sensor device is disclosed. FIG. 1 shows a top view of an image sensor device in this embodiment of the invention.

Referring to FIG. 1, an image sensor device 10 comprises a substrate 12 comprising a central area 14 and a peripheral area 16, a sensing area 18 located at the central area 14 of the substrate 12, a plurality of I/O pads 20 located at the peripheral area 16 of the substrate 12, and a plurality of metal wires 22 disposed above the substrate 12 which extend from the central area 14 to the peripheral area 16 of the substrate 12 and are electrically connected to the I/O pads 20. Specifically, none of the metal wires 22 overlies the sensing area 18.

In one embodiment, the sensing area 18 may comprise various photoelectric conversion units, for example, photodiodes.

As shown in FIG. 1, in this embodiment, one of the I/O pads 20 is electrically connected to one of the metal wires 22.

In this embodiment, the image sensor device 10 further comprises an external circuit 24 electrically connecting to the I/O pads 20 and another substrate 26.

Specifically, the voltage of the metal wires 22 is controlled by the another substrate 26 through the external circuit 24.

In this embodiment, the another substrate 26 may be made of ceramic material, silicon, glass or other suitable materials.

In this embodiment, the process for controlling movement of droplets above the image sensor device 10 is disclosed as follows. First, a proper voltage provided from the another substrate 26 is transmitted to a first I/O pad 20′ and a first metal wire 22′ controlled by the first I/O pad 20′ through the external circuit 24 to turn on the voltage of the first metal wire 22′. At this time, droplets underneath the first metal wire 22′ move towards a second metal wire 22″ due to the electric field generated by the first metal wire 22′. Next, another proper voltage provided from the another substrate 26 is transmitted to a second I/O pad 20″ and the second metal wire 22″ controlled by the second I/O pad 20″ through the external circuit 24 to turn on the voltage of the second metal wire 22″ and turn off the voltage of the first metal wire 22′, simultaneously. At this time, the droplets underneath the second metal wire 22″ move towards a third metal wire 22′″ due to the electric field generated by the second metal wire 22″. The steps of turning on/off the voltage of the metal wires are repeated. The droplets above the image sensor device 10 are then successfully removed out of the image sensor device 10 in accordance with a desired speed and direction.

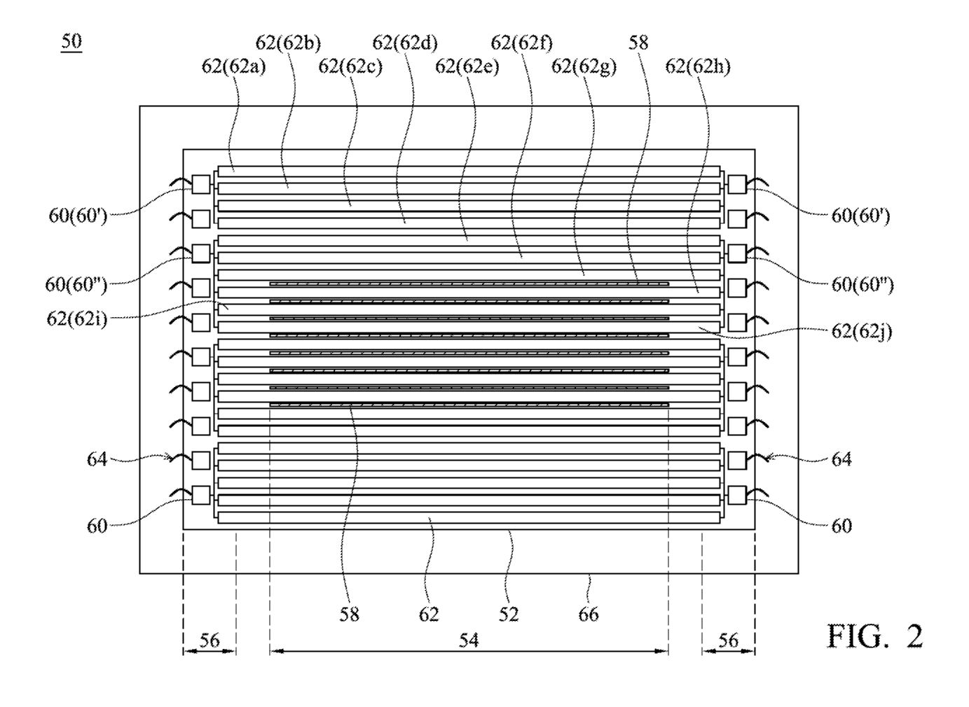

In accordance with another embodiment of the invention, an image sensor device is disclosed. FIG. 2 shows a top view of an image sensor device in this embodiment of the invention.

Referring to FIG. 2, an image sensor device 50 comprises a substrate 52 comprising a central area 54 and a peripheral area 56, a sensing area 58 located at the central area 54 of the substrate 52, a plurality of I/O pads 60 located at the peripheral area 56 of the substrate 52, and a plurality of metal wires 62 disposed above the substrate 52 which extend from the central area 54 to the peripheral area 56 of the substrate 52 and are electrically connected to the I/O pads 60. Specifically, none of the metal wires 62 overlies the sensing area 58.

In one embodiment, the sensing area 58 may comprise various photoelectric conversion units, for example, photodiodes.

As shown in FIG. 2, in this embodiment, one of the I/O pads 60 is electrically connected to the plurality of metal wires 62.

In this embodiment, the image sensor device 50 further comprises an external circuit 64 electrically connecting to the I/O pads 60 and another substrate 66.

Specifically, the voltage of the metal wires 62 is controlled by the another substrate 66 through the external circuit 64.

In this embodiment, the another substrate 66 may be made of ceramic material, silicon, glass or other suitable materials.

In this embodiment, the process for controlling movement of droplets above the image sensor device 50 is disclosed as follows. First, a proper voltage provided from the another substrate 66 is transmitted to a first I/O pad 60′ and a first metal wire group (comprising a first metal wire 62a, a second metal wire 62b, a third metal wire 62c and a fourth metal wire 62d) controlled by the first I/O pad 60′ through the external circuit 64 to turn on the voltage of the first metal wire group. At this time, droplets underneath the first metal wire group move towards a second metal wire group due to the electric field generated by the first metal wire group. Next, another proper voltage provided from the another substrate 66 is transmitted to a second I/O pad 60″ and the second metal wire group (comprising a fifth metal wire 62e, a sixth metal wire 62f, a seventh metal wire 62g, an eighth metal wire 62h, a ninth metal wire 62i and a tenth metal wire 62j) controlled by the second I/O pad 60″ through the external circuit 64 to turn on the voltage of the second metal wire group and turn off the voltage of the first metal wire group, simultaneously. At this time, the droplets underneath the second metal wire group move towards a third metal wire group due to the electric field generated by the second metal wire group. The steps of turning on/off the voltage of the metal wire groups are repeated. The droplets above the image sensor device 50 are then successfully removed out of the image sensor device 50 in accordance with a desired speed and direction.

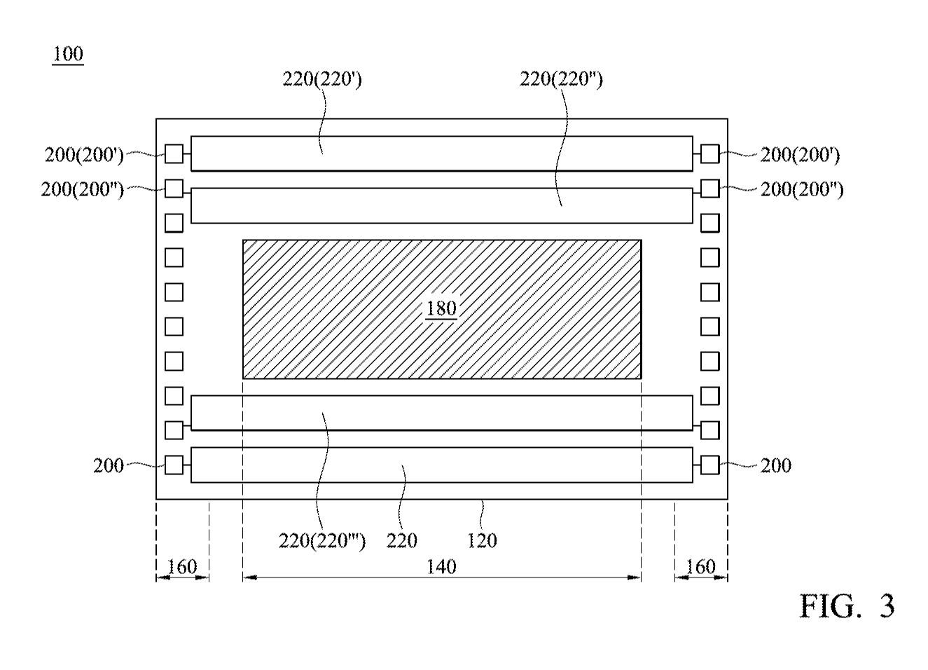

In accordance with another embodiment of the invention, an image sensor device is disclosed. FIG. 3 shows a top view of an image sensor device in this embodiment of the invention.

Referring to FIG. 3, an image sensor device 100 comprises a substrate 120 comprising a central area 140 and a peripheral area 160, a sensing area 180 located at the central area 140 of the substrate 120, a plurality of I/O pads 200 located at the peripheral area 160 of the substrate 120, and a plurality of metal wires 220 disposed above the substrate 120 which extend from the central area 140 to the peripheral area 160 of the substrate 120 and are electrically connected to the I/O pads 200. Specifically, none of the metal wires 220 overlies the sensing area 180.

In one embodiment, the sensing area 180 may comprise various photoelectric conversion units, for example, photodiodes.

As shown in FIG. 3, in this embodiment, one of the I/O pads 200 is electrically connected to one of the metal wires 220.

In this embodiment, the image sensor device 100 further comprises an internal circuit (not shown) disposed in the substrate 120 and electrically connecting to the I/O pads 200.

Specifically, the voltage of the metal wires 220 is controlled by the image sensor device 100 through the internal circuit.

In this embodiment, the process for controlling movement of droplets above the image sensor device 100 is disclosed as follows. First, a proper voltage provided from the image sensor device 100 is transmitted to a first I/O pad 200′ and a first metal wire 220′ controlled by the first I/O pad 200′ through the internal circuit to turn on the voltage of the first metal wire 220′. At this time, droplets underneath the first metal wire 220′ move towards a second metal wire 220″ due to the electric field generated by the first metal wire 220′. Next, another proper voltage provided from the image sensor device 100 is transmitted to a second I/O pad 200″ and the second metal wire 220″ controlled by the second I/O pad 200″ through the internal circuit to turn on the voltage of the second metal wire 220″ and turn off the voltage of the first metal wire 220′, simultaneously. At this time, the droplets underneath the second metal wire 220″ move towards a third metal wire 220′″ due to the electric field generated by the second metal wire 220″. The steps of turning on/off the voltage of the metal wires are repeated. The droplets above the image sensor device 100 are then successfully removed out of the image sensor device 100 in accordance with a desired speed and direction.

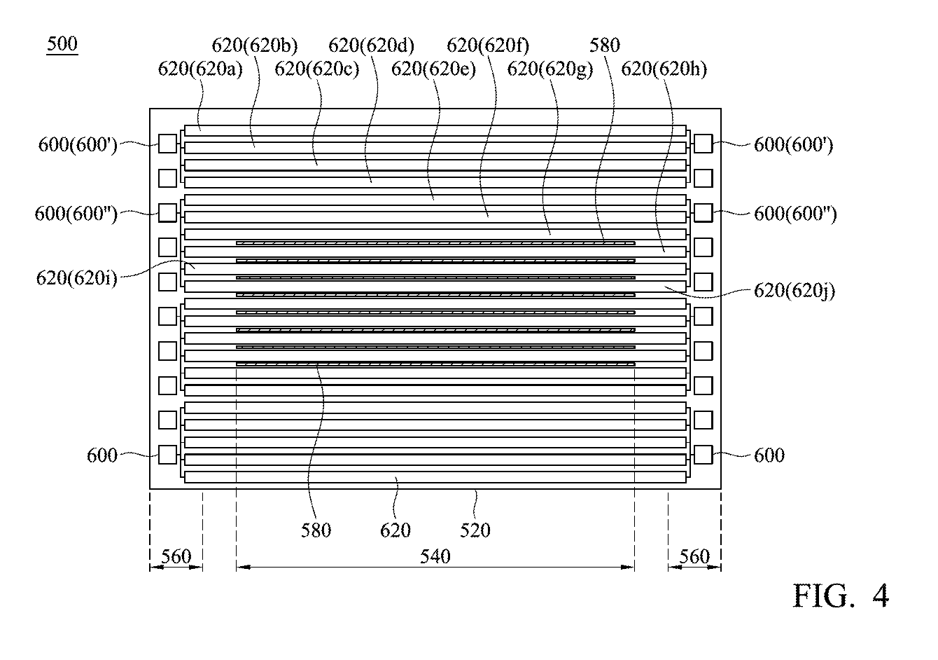

In accordance with another embodiment of the invention, an image sensor device is disclosed. FIG. 4 shows a top view of an image sensor device in this embodiment of the invention.

Referring to FIG. 4, an image sensor device 500 comprises a substrate 520 comprising a central area 540 and a peripheral area 560, a sensing area 580 located at the central area 540 of the substrate 520, a plurality of I/O pads 600 located at the peripheral area 560 of the substrate 520, and a plurality of metal wires 620 disposed above the substrate 520 which extend from the central area 540 to the peripheral area 560 of the substrate 520 and are electrically connected to the I/O pads 600. Specifically, none of the metal wires 620 overlies the sensing area 580.

In one embodiment, the sensing area 580 may comprise various photoelectric conversion units, for example, photodiodes.

As shown in FIG. 4, in this embodiment, one of the I/O pads 600 is electrically connected to the plurality of metal wires 620.

In this embodiment, the image sensor device 500 further comprises an internal circuit (not shown) disposed in the substrate 520 and electrically connecting to the I/O pads 600.

Specifically, the voltage of the metal wires 620 is controlled by the image sensor device 500 through the internal circuit.

In this embodiment, the process for controlling movement of droplets above the image sensor device 500 is disclosed as follows. First, a proper voltage provided from the image sensor device 500 is transmitted to a first I/O pad 600′ and a first metal wire group (comprising a first metal wire 620a, a second metal wire 620b, a third metal wire 620c and a fourth metal wire 620d) controlled by the first I/O pad 600′ through the internal circuit to turn on the voltage of the first metal wire group. At this time, droplets underneath the first metal wire group move towards a second metal wire group due to the electric field generated by the first metal wire group. Next, another proper voltage provided from the image sensor device 500 is transmitted to a second I/O pad 600″ and the second metal wire group (comprising a fifth metal wire 620e, a sixth metal wire 620f, a seventh metal wire 620g, an eighth metal wire 620h, a ninth metal wire 620i and a tenth metal wire 620j) controlled by the second I/O pad 600″ through the internal circuit to turn on the voltage of the second metal wire group and turn off the voltage of the first metal wire group, simultaneously. At this time, the droplets underneath the second metal wire group move towards a third metal wire group due to the electric field generated by the second metal wire group. Additionally, the steps of turning on/off the voltage of the metal wire groups are repeated. The droplets above the image sensor device 500 are then successfully removed out of the image sensor device 500 in accordance with a desired speed and direction.

In the invention, the metal wires (a metal gate) with the specific wire density, gap width, wire width, wire thickness and pad/wire arrangement (for example, one I/O pad electrically connecting to one metal wire or one I/O pad electrically connecting to one metal wire group (comprising a plurality of metal wires)) extended from the central area to the peripheral area of the substrate are disposed above the image sensor device and provide proper potential difference and electric-field direction through an independent external circuit (for example, electrically connecting to a printed circuit board) or an independent internal circuit capable of independently controlling the turning on/off of the voltage, the timing of the turning on/off of the voltage and the voltage values of each metal wire or each group of the metal wires to successfully pull droplets above the image sensor device and make the droplets move in accordance with a desired speed and direction. In the invention, the density of the metal wires above the image sensor device is adjusted and the sensing area is exposed. In this situation, the sensing effect of the sensing area remains and the applied voltage is effectively reduced. Additionally, the internal circuit capable of controlling the metal wires is integrated into the same image sensor device, effectively reducing cost.

It will be apparent to those skilled in the art that various modifications and variations can be made to the disclosed embodiments. It is intended that the specification and examples be considered as exemplary only, with the true scope of the invention being indicated by the following claims and their equivalents.

What is claimed is:

1. An image sensor device, comprising:
a substrate comprising a central area and a peripheral area;
a sensing area located at the central area of the substrate;
a plurality of I/O pads located at the peripheral area of the substrate; and
a plurality of metal wires disposed above the substrate which extend from the central area to the peripheral area of the substrate and are electrically connected to the I/O pads, wherein none of the metal wires overlies the sensing area.

2. The image sensor device as claimed in claim 1, wherein the sensing area comprises photoelectric conversion units.

3. The image sensor device as claimed in claim 2, wherein the photoelectric conversion unit comprises a photodiode (PD).

4. The image sensor device as claimed in claim 1, wherein one of the I/O pads is electrically connected to one of the metal wires.

5. The image sensor device as claimed in claim 1, wherein one of the I/O pads is electrically connected to the plurality of metal wires.

6. The image sensor device as claimed in claim 4, further comprising an external circuit electrically connecting to the I/O pads and another substrate.

7. The image sensor device as claimed in claim 5, further comprising an external circuit electrically connecting to the I/O pads and another substrate.

8. The image sensor device as claimed in claim 6, wherein the voltage of the metal wires is controlled by the another substrate through the external circuit.

9. The image sensor device as claimed in claim 7, wherein the voltage of the metal wires is controlled by the another substrate through the external circuit.

10. The image sensor device as claimed in claim 4, further comprising an internal circuit disposed in the substrate which is electrically connected to the I/O pads.

11. The image sensor device as claimed in claim 5, further comprising an internal circuit disposed in the substrate which is electrically connected to the I/O pads.

12. The image sensor device as claimed in claim 10, wherein the voltage of the metal wires is controlled by the image sensor device through the internal circuit.

13. The image sensor device as claimed in claim 11, wherein the voltage of the metal wires is controlled by the image sensor device through the internal circuit.
